(19) United States
(12) Patent Application Publication
(10) Pub. No.: US 2025/0372510 A1
(43) Pub. Date: Dec. 4, 2025

(54) SEMICONDUCTOR DEVICE AND MANUFACTURING METHOD THEREOF

(71) Applicant: SILICONWARE PRECISION INDUSTRIES CO., LTD., Taichung City (TW)

(72) Inventors: Yi-Chun LAI, Taichung City (TW); Hsuan-Jen WANG, Taichung City (TW); Rung-Jeng LIN, Taichung City (TW)

(21) Appl. No.: 18/768,762

(22) Filed: Jul. 10, 2024

(30) Foreign Application Priority Data
May 31, 2024 (TW) 113120330

(51) Int. Cl. H01L 23/522; H01L 21/768; H01L 23/532

(52) U.S. Cl. CPC H01L 23/5227; H01L 21/76885; H01L 23/5226; H01L 23/5329

(57) ABSTRACT

A semiconductor device and a manufacturing method thereof are provided, which mainly form a first wiring layer, a bottom routing layer, and a plurality of conductive pillars on a carrier structure, and the plurality of conductive pillars are electrically connected to the first wiring layer and the bottom routing layer. Next, an encapsulation layer covering the plurality of conductive pillars is formed on the first wiring layer and the bottom routing layer, wherein the encapsulation layer includes a magnetic material. Then, a top routing layer and a second wiring layer are formed on the encapsulation layer, and the plurality of conductive pillars are electrically connected to the top routing layer and the second wiring layer, wherein the bottom routing layer, the plurality of conductive pillars, and the top routing layer constitute a conductor structure, and the conductor structure and the encapsulation layer confined thereby constitute an inductor module.

### CROSS-REFERENCE TO RELATED APPLICATIONS

The present application is based upon and claims the right of priority to TW Patent Application No. 113120330, filed May 31, 2024, the disclosure of which is hereby incorporated by reference herein in its entirety for all purposes.

### BACKGROUND

### Technical Field

The present disclosure relates to a semiconductor device, and more particularly, to a semiconductor device integrated with an inductor module and a manufacturing method thereof.

### Description of Related Art

With the booming development of portable electronic products in recent years, the development of various related products is also in the trend of high density, high performance, and lightness, thinness, shortness, and smallness. To this end, the industry has developed a variety of integrated multi-functional packaging types to meet the requirements of light, thin, short, small and high-density electronic products.

For example, wireless communication technology has been widely used in various consumer electronic products to facilitate the reception or transmission of various wireless signals. Among these technologies, a patch antenna is widely used in the wireless communication module of a cell phone, a personal digital assistant, and other electronic products due to its small size, light weight, and ease of manufacturing. In communication or high-frequency semiconductor devices, it is often necessary to electrically connect several radio-frequency passive components, such as resistors, inductors, capacitors, and oscillators, to the packaged semiconductor chip in order to enable the semiconductor chip to have a specific current characteristic or to emit a signal.

In addition, with the evolution of technologies, the demand for electronic products tends to heterogeneous integration, giving rise to a 3D multi-chip package module. A semiconductor package 1 is shown in FIG. 1, in which an inductor device 11 is bonded on a semiconductor chip 10 and electrically connected to the semiconductor chip 10 via a circuit structure 12.

However, the conventional inductor device 11 occupies too much surface areas of the semiconductor chip 10, making it difficult to reduce the size of the semiconductor package 1, which not only does not meet the requirement of a semiconductor package that is light, thin, short and small, but also lacks the protection of electromagnetic shielding.

Therefore, how to overcome the above problems of the prior art has become an urgent problem to be solved.

### SUMMARY

In view of the various deficiencies of the prior art, the present disclosure provides a semiconductor device, which comprises: a carrier structure; a first wiring layer formed on the carrier structure; a bottom routing layer formed on the carrier structure; a plurality of conductive pillars disposed on the carrier structure and electrically connected to the first wiring layer and the bottom routing layer; an encapsulation layer formed on the first wiring layer and the bottom routing layer and covering the plurality of conductive pillars, wherein the encapsulation layer includes a magnetic material; a top routing layer formed on the encapsulation layer; and a second wiring layer formed on the encapsulation layer, wherein the plurality of conductive pillars are electrically connected to the top routing layer and the second wiring layer, wherein the bottom routing layer, the plurality of conductive pillars, and the top routing layer constitute a conductor structure, and the conductor structure and the encapsulation layer confined by the conductor structure constitute an inductor module.

The present disclosure further provides a method of manufacturing a semiconductor device, the method comprises: providing a carrier structure; forming a first wiring layer, a bottom routing layer, and a plurality of conductive pillars on the carrier structure, and electrically connecting the plurality of conductive pillars to the first wiring layer and the bottom routing layer; forming an encapsulation layer covering the plurality of conductive pillars on the first wiring layer and the bottom routing layer, wherein the encapsulation layer includes a magnetic material; and forming a top routing layer and a second wiring layer on the encapsulation layer, and electrically connecting the plurality of conductive pillars to the top routing layer and the second wiring layer, wherein the bottom routing layer, the plurality of conductive pillars, and the top routing layer constitute a conductor structure, and the conductor structure and the encapsulation layer confined by the conductor structure constitute an inductor module.

In the aforementioned semiconductor device and method, the first wiring layer is electrically connected to the carrier structure.

In the aforementioned semiconductor device and method, each of the first wiring layer, the bottom routing layer, the top routing layer, and the second wiring layer is a redistribution layer (RDL).

In the aforementioned semiconductor device and method, the first wiring layer includes a first insulator and a plurality of first conductive wirings bonded to the first insulator, the bottom routing layer includes a plurality of bottom wirings, the top routing layer includes a plurality of top wirings, and the second wiring layer includes a second insulator and a plurality of second conductive wirings bonded to the second insulator.

In the aforementioned semiconductor device and method, each of the conducive pillars has a first end portion and a second end portion opposing the first end portion, the first end portions are optionally electrically connected to the plurality of bottom wirings and/or the plurality of first conductive wirings, and the second end portions are optionally electrically connected to the plurality of top wirings and/or the plurality of second conductive wirings.

In the aforementioned semiconductor device and method, the encapsulation layer has a first surface and a second surface opposing the first surface, the encapsulation layer is disposed on the first wiring layer and the bottom routing layer via the first surface thereof, and the plurality of conductive pillars are exposed out from the second surface of the encapsulation layer.

As can be seen from the above, the semiconductor device and its manufacturing method of the present disclosure mainly form a three-dimensional coil inductor by a top routing layer, a plurality of conductive pillars, a bottom routing layer, and an encapsulation layer with magnetic material to increase magnetic flux and provide a shielding effect. Moreover, the use of the three-dimensional coil inductor does not occupy a large surface area of the carrier structure, and the volume can be reduced by changing the RDL layout as needed, which is advantageous for meeting the requirement of miniaturization.

### BRIEF DESCRIPTION OF THE DRAWINGS

FIG. 1 is a schematic cross-sectional view of a conventional semiconductor package.

FIG. 2A to FIG. 2D are schematic cross-sectional views illustrating a manufacturing method of a semiconductor device according to the present disclosure.

FIG. 3 is a schematic top view of an inductor module of the semiconductor device according to the present disclosure.

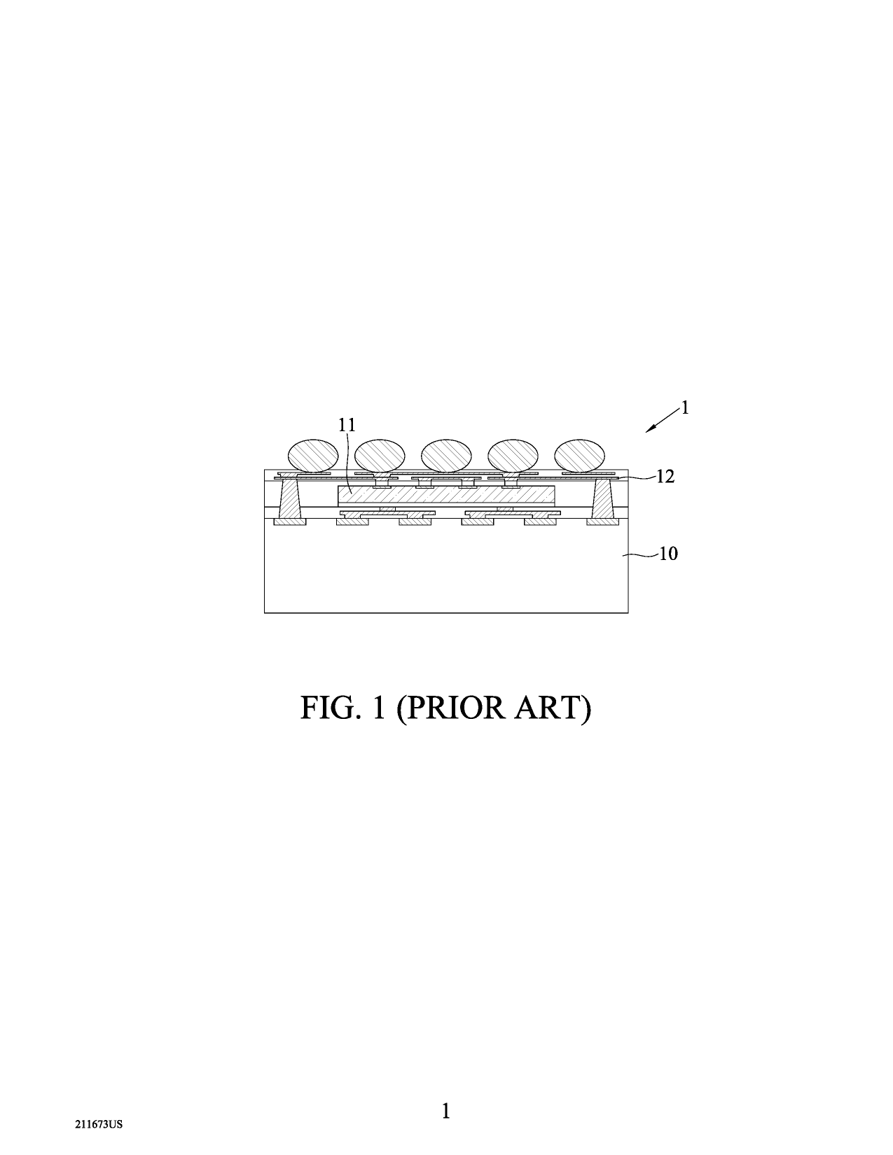

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “upper,” “first,” “second,” “a,” “one” and the like are merely used for clear explanation rather than limiting the practicable scope of the present disclosure, and thus, alterations or adjustments of the relative relationships thereof without essentially altering the technical contents should still be considered in the practicable scope of the present disclosure.

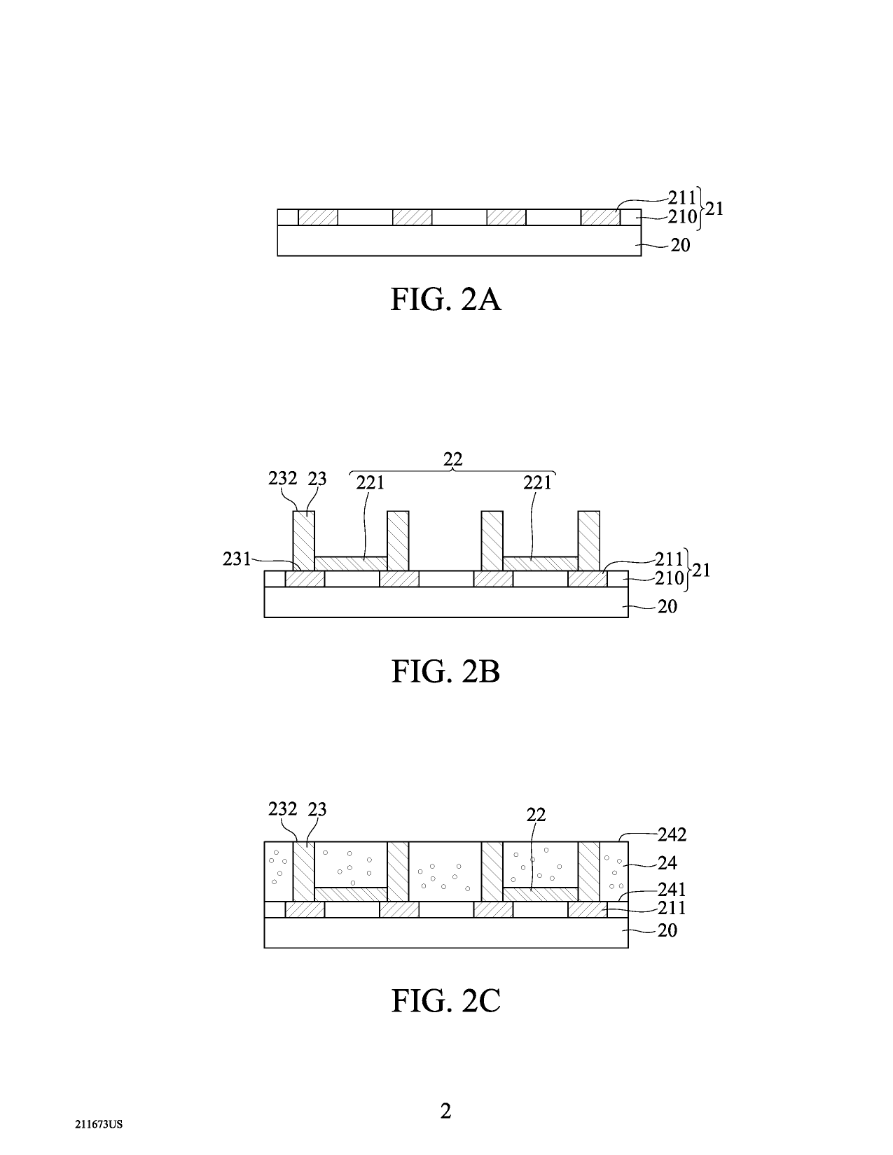

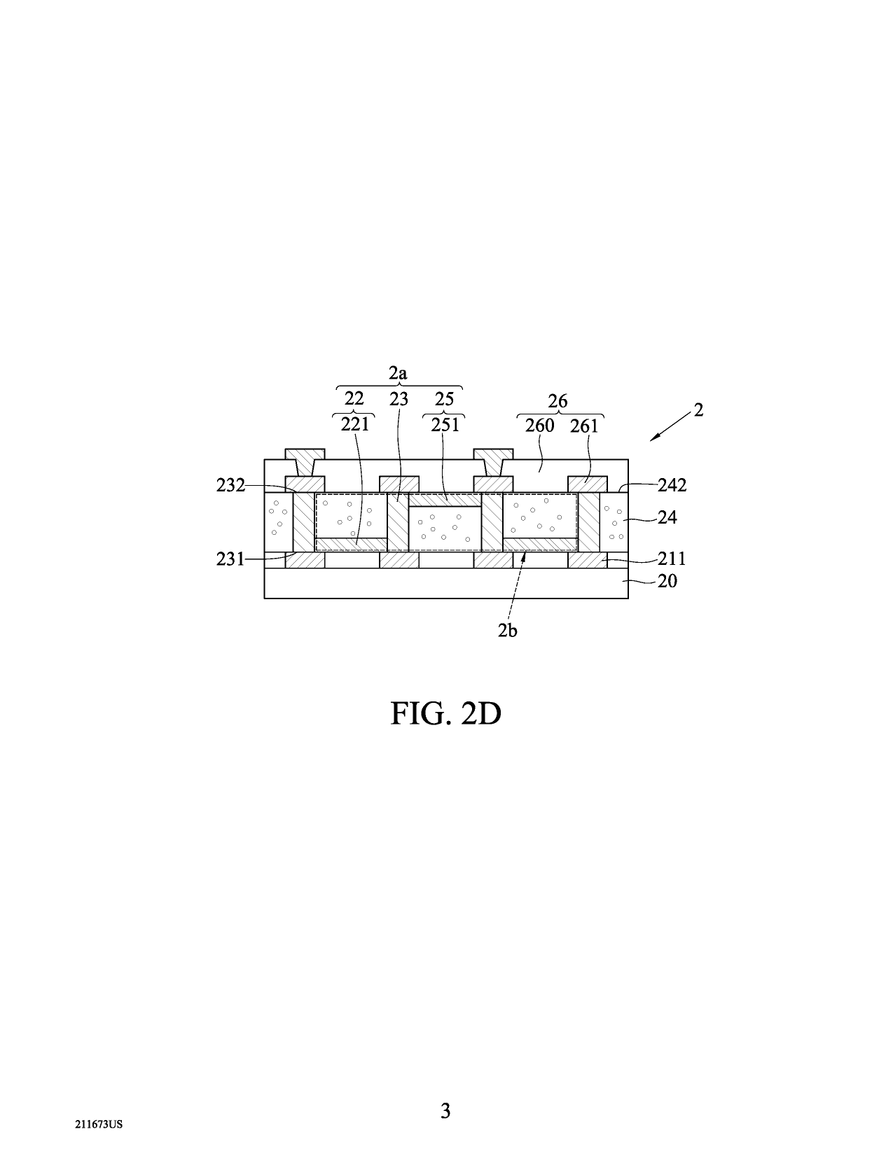

FIG. 2A to FIG. 2D are schematic cross-sectional views illustrating a manufacturing method of a semiconductor device 2 according to the present disclosure.

As shown in FIG. 2A, a carrier structure 20 is provided. At least one first wiring layer 21 is formed on the carrier structure 20 and includes a first insulator 210 and a plurality of first conductive wirings 211 bonded to the first insulator 210. In one embodiment, only one first wiring layer 21 is shown. In another embodiment, a plurality of first wiring layers 21 may be formed.

The carrier structure 20 may be a wafer, a chip, a substrate, an interposer, a general carrier board, or the like. The first wiring layer 21 may optionally be electrically connected to the carrier structure 20. Moreover, the first wiring layer 21 may be a redistribution layer (RDL), and the first insulator 210 may be made of polybenzoxazole (PBO), polyimide (PI), prepreg (PP), or other dielectric materials. The first conductive wirings 211 are made of, for example, copper metal.

As shown in FIG. 2B, a bottom routing layer 22 and a plurality of conductive pillars 23 are formed on the carrier structure 20 (the first wiring layer 21). The bottom routing layer 22 includes a plurality of bottom wirings 221, and the plurality of conductive pillars 23 are electrically connected to the plurality of bottom wirings 221 of the bottom routing layer 22 and the plurality of first conductive wirings 211 of the first wiring layer 21.

In an embodiment, the bottom routing layer 22 may be made by an RDL process. Each of the plurality of conductive pillars 23 has a first end portion 231 and a second end portion 232 opposing the first end portion 231, and the first end portions 231 of the plurality of conductive pillars 23 may optionally/selectively be electrically connected to the plurality of bottom wirings 221 and/or the plurality of first conductive wirings 211.

In another embodiment, the first wiring layer 21 and the bottom routing layer 22 may be made by an RDL process, so that the first wiring layer 21 and the bottom routing layer 22 may be made in the same layer at the same time.

As shown in FIG. 2C, an encapsulation layer 24 is formed on the first wiring layer 21 and the bottom routing layer 22 and covers the plurality of conductive pillars 23.

In an embodiment, the encapsulation layer 24 is formed of a material, such as polyimide (PI), dry film, epoxy resin, or molding compound. For example, the encapsulation layer 24 may be formed on the carrier structure 20 by a process, such as liquid compound, injection, lamination, or compression molding, and so forth.

The encapsulation layer 24 includes a magnetic material (e.g., magnetic powder) to improve a magnetic permeability. In an embodiment, the encapsulation layer 24 can be made by powdering ferrite, mixing ferrite powder with epoxy resin, and stirring the mixture.

Furthermore, the encapsulation layer 24 has a first surface 241 and a second surface 242 opposing the first surface 241. The encapsulation layer 24 is disposed on the first wiring layer 21 and the bottom routing layer 22 with its first surface 241, and the second end portions 232 of the plurality of conductive pillars 23 can be exposed out from the second surface 242 of the encapsulation layer 24 by means of, for example, a thinning process.

As shown in FIG. 2D, a top routing layer 25 and at least one second wiring layer 26 are formed on the second surface 242 of the encapsulation layer 24. The top routing layer 25 includes a plurality of top wirings 251, and the second wiring layer 26 includes a second insulator 260 and a plurality of second conductive wirings 261 bonded to the second insulator 260. The second end portions 232 of the plurality of conductive pillars 23 may optionally/selectively be electrically connected to the plurality of top wirings 251 of the top routing layer 25 and/or the plurality of second conductive wirings 261 of the second wiring layer 26. The top routing layer 25 and the second wiring layer 26 may be made by an RDL process.

In addition, the second wiring layer 26 and the top routing layer 25 may be made by an RDL process, so that the second wiring layer 26 and the top routing layer 25 may be made in the same layer at the same time.

In an embodiment, a conductor structure 2a is composed of the top routing layer 25 including the plurality of top wirings 251, the plurality of conductive pillars 23, and the bottom routing layer 22 including the plurality of bottom wirings 221. An inductor module 2b is composed of the conductor structure 2a and the encapsulation layer 24 including a magnetic material and confined by the conductor structure 2a. As such, the semiconductor device 2 is manufactured.

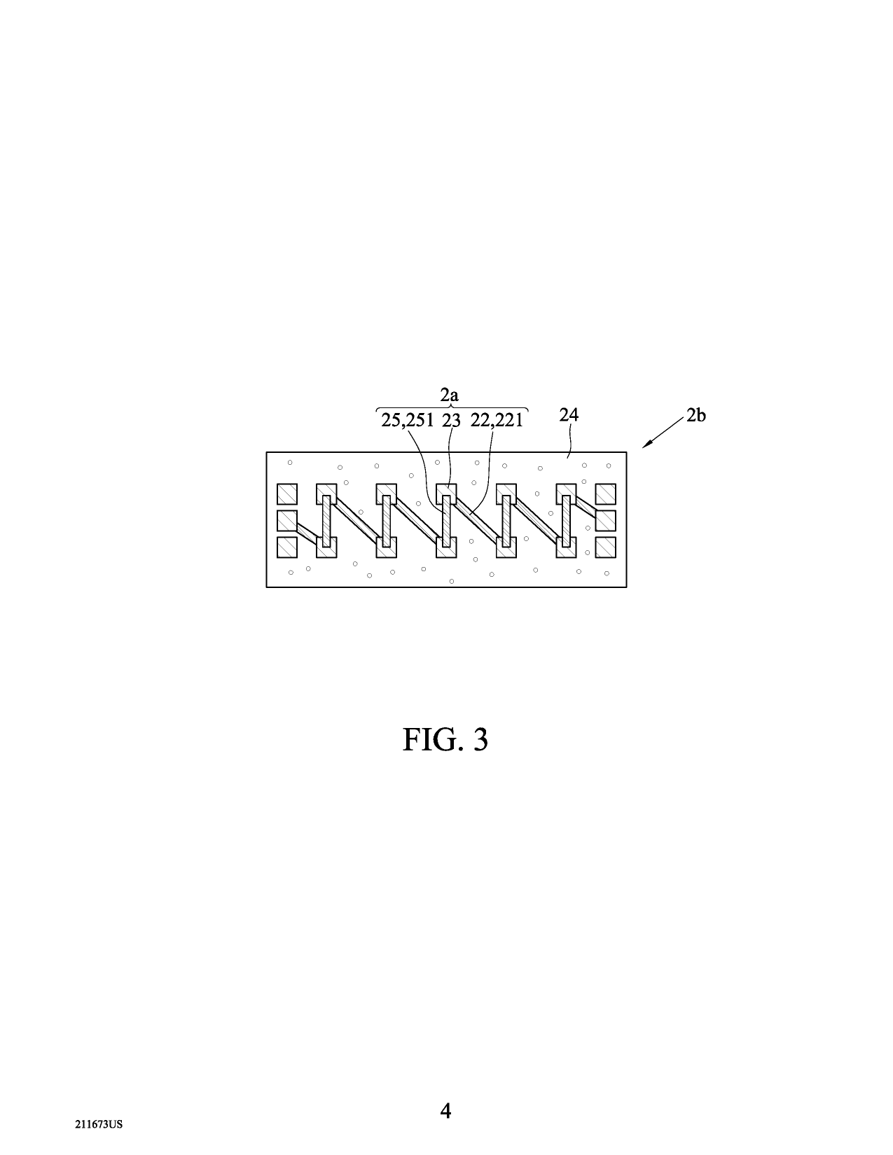

Please also refer to FIG. 3 together, which is a schematic partial top view of the inductor module 2b of the semiconductor device 2 according to the present disclosure. As shown in FIG. 3, the top routing layer 25 including the plurality of top wirings 251, the plurality of conductive pillars 23, and the bottom routing layer 22 including the plurality of bottom wirings 221 are used to form the conductor structure 2a. In the conductor structure 2a, two ends of one top wiring 251 are connected to two second end portions 232 of two conductive pillars 23, respectively, and then one end of one bottom wiring 221 is connected to one first end portion 231 of one of the two conductive pillars 23, and another end of the one bottom wiring 221 is connected to another first end portion 231 of another conductive pillar 23. In this way, the plurality of conductive pillars 23 are sequentially connected to form the conductor structure 2a in a form of a loop coil. Further, the encapsulation layer 24 including a magnetic material is confined by the conductor structure 2a, such that the conductor structure 2a and the encapsulation layer 24 confined thereby generate magnetic flux to form the inductor module 2b. Accordingly, by adding the high magnetic permeability material to the encapsulation layer 24, the present disclosure improves the magnetic flux generated by the conductor structure 2a, which is advantageous for increasing the inductance value.

Therefore, the present disclosure mainly adds a high magnetic permeability material to the encapsulation layer 24, and enables the conductor structure 2a, which is composed of the top routing layer 25 including the plurality of top wirings 251, the plurality of conductive pillars 23, and the bottom routing layer 22 including the plurality of bottom wirings 221, to confine the encapsulation layer 24 so as to generate magnetic flux, thereby forming the semiconductor device 2 including the inductor module 2b. Accordingly, the present disclosure can adopt RDL distribution and magnetic materials to from an inductor-like coil loop (i.e., inductor module) to improve electrical performance, and the encapsulation layer 24 has magnetic properties, and the plurality of conductive pillars 23 are connected to the top routing layer 25 and the bottom routing layer 22, thereby reducing the size of the inductor module 2b without being limited by space and having a shielding effect.

The present disclosure also provides a semiconductor device 2, which includes: a carrier structure 20, a first wiring layer 21, a bottom routing layer 22, a plurality of conductive pillars 23, an encapsulation layer 24, a top routing layer 25, and a second wiring layer 26.

The first wiring layer 21 is formed on the carrier structure 20 and is optionally electrically connected to the carrier structure 20.

The bottom routing layer 22 and the plurality of conductive pillars 23 are disposed on the carrier structure 20, and the plurality of conductive pillars 23 are electrically connected to the bottom routing layer 22 and the first wiring layer 21.

The encapsulation layer 24 is formed on the first wiring layer 21 and the bottom routing layer 22, and covers the plurality of conductive pillars 23. Further, the encapsulation layer 24 includes a magnetic material.

The top routing layer 25 and the second wiring layer 26 are formed on the encapsulation layer 24, and the plurality of conductive pillars 23 are electrically connected to the top routing layer 25 and the second wiring layer 26.

The top routing layer 25, the plurality of conductive pillars 23, and the bottom routing layer 22 constitute a conductor structure 2a, and the conductor structure 2a and the encapsulation layer 24 having a magnetic material and confined by the conductor structure 2a constitute an inductor module 2b.

To sum up, the semiconductor device and its manufacturing method of the present disclosure mainly form a three-dimensional coil inductor by a top routing layer, a plurality of conductive pillars, a bottom routing layer, and an encapsulation layer with magnetic material to increase magnetic flux and provide a shielding effect. Moreover, the use of the three-dimensional coil inductor does not occupy a large surface area of the carrier structure, and the volume can be reduced by changing the RDL layout as needed, which is advantageous for meeting the requirement of miniaturization.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A semiconductor device, comprising:
a carrier structure;
a first wiring layer formed on the carrier structure;
a bottom routing layer formed on the carrier structure;
a plurality of conductive pillars disposed on the carrier structure and electrically connected to the first wiring layer and the bottom routing layer;
an encapsulation layer formed on the first wiring layer and the bottom routing layer and covering the plurality of conductive pillars, wherein the encapsulation layer includes a magnetic material;
a top routing layer formed on the encapsulation layer; and
a second wiring layer formed on the encapsulation layer, wherein the plurality of conductive pillars are electrically connected to the top routing layer and the second wiring layer, wherein the bottom routing layer, the plurality of conductive pillars, and the top routing layer constitute a conductor structure, and the conductor structure and the encapsulation layer confined by the conductor structure constitute an inductor module.

2. The semiconductor device of claim 1, wherein the first wiring layer is electrically connected to the carrier structure.

3. The semiconductor device of claim 1, wherein each of the first wiring layer, the bottom routing layer, the top routing layer, and the second wiring layer is a redistribution layer.

4. The semiconductor device of claim 1, wherein the first wiring layer includes a first insulator and a plurality of first conductive wirings bonded to the first insulator, the bottom routing layer includes a plurality of bottom wirings, the top routing layer includes a plurality of top wirings, and the second wiring layer includes a second insulator and a plurality of second conductive wirings bonded to the second insulator.

5. The semiconductor device of claim 4, wherein each of the conducive pillars has a first end portion and a second end portion opposing the first end portion, the first end portions are optionally electrically connected to the plurality of bottom wirings and/or the plurality of first conductive wirings, and the second end portions are optionally electrically connected to the plurality of top wirings and/or the plurality of second conductive wirings.

6. The semiconductor device of claim 1, wherein the encapsulation layer has a first surface and a second surface opposing the first surface, the encapsulation layer is disposed on the first wiring layer and the bottom routing layer via the first surface thereof, and the plurality of conductive pillars are exposed out from the second surface of the encapsulation layer.

7. A method of manufacturing a semiconductor device, the method comprising:
providing a carrier structure;
forming a first wiring layer, a bottom routing layer, and a plurality of conductive pillars on the carrier structure, and electrically connecting the plurality of conductive pillars to the first wiring layer and the bottom routing layer;
forming an encapsulation layer covering the plurality of conductive pillars on the first wiring layer and the bottom routing layer, wherein the encapsulation layer includes a magnetic material; and
forming a top routing layer and a second wiring layer on the encapsulation layer, and electrically connecting the plurality of conductive pillars to the top routing layer and the second wiring layer, wherein the bottom routing layer, the plurality of conductive pillars, and the top routing layer constitute a conductor structure, and the conductor structure and the encapsulation layer confined by the conductor structure constitute an inductor module.

8. The method of claim 7, wherein the first wiring layer is electrically connected to the carrier structure.

9. The method of claim 7, wherein each of the first wiring layer, the bottom routing layer, the top routing layer, and the second wiring layer is a redistribution layer.

10. The method of claim 7, wherein the first wiring layer includes a first insulator and a plurality of first conductive wirings bonded to the first insulator, the bottom routing layer includes a plurality of bottom wirings, the top routing layer includes a plurality of top wirings, and the second wiring layer includes a second insulator and a plurality of second conductive wirings bonded to the second insulator.

11. The method of claim 10, wherein each of the conducive pillars has a first end portion and a second end portion opposing the first end portion, the first end portions are optionally electrically connected to the plurality of bottom wirings and/or the plurality of first conductive wirings, and the second end portions are optionally electrically connected to the plurality of top wirings and/or the plurality of second conductive wirings.

12. The method of claim 7, wherein the encapsulation layer has a first surface and a second surface opposing the first surface, the encapsulation layer is disposed on the first wiring layer and the bottom routing layer via the first surface thereof, and the plurality of conductive pillars are exposed out from the second surface of the encapsulation layer.
